(19) United States
(12) Patent Application Publication
(10) Pub. No.: US 2020/0258762 A1
(43) Pub. Date: Aug. 13, 2020

(54) TEMPERATURE CONTROL APPARATUS

(71) Applicant: POINT ENGINEERING CO., LTD., Asan (KR)

(72) Inventor: Bum Mo AHN, Suwon (KR)

(21) Appl. No.: 16/783,013

(22) Filed: Feb. 5, 2020

(30) Foreign Application Priority Data
Feb. 7, 2019 (KR) 10-2019-0014236

(51) Int. Cl. H01L 21/67; G05D 23/01; H01L 21/768

(52) U.S. Cl. CPC H01L 21/67248; G05D 23/01; G01K 13/10; H01L 21/67063; H01L 21/76867

(57) ABSTRACT

The present invention relates generally to a temperature control apparatus capable of controlling the temperature of a product using a temperature control material. More particularly, the present invention relates to a temperature control apparatus capable of uniformly controlling the temperature of a product by reducing a temperature deviation of a temperature control material flowing inside the product.

### CROSS REFERENCE TO RELATED APPLICATION

The present application claims priority to Korean Patent Application No. 10-2019-0014236, filed Feb. 7, 2019, the entire contents of which is incorporated herein for all purposes by this reference.

### BACKGROUND OF THE INVENTION

### Field of the Invention

The present invention relates to a temperature control apparatus capable of controlling the temperature of a product using a temperature control material.

### Description of the Related Art

As a technique for depositing a thin film on a semiconductor substrate or glass, chemical vapor deposition (CVD) or atomic layer deposition (ALD), which are thin-film deposition techniques based on chemical reaction, is used.

Equipment for performing thin-film deposition, such as CVD or ALD, is used to manufacture semiconductor devices. Such thin-film deposition equipment usually includes a showerhead provided inside a chamber to supply a reaction process fluid required for depositing a thin film on a wafer. The showerhead serves to spray the reaction process fluid onto the wafer in the proper distribution range required for thin film deposition.

One example of the showerhead is disclosed in Korean Patent No. 10-0769522 (hereinafter, referred to as “Patent Document 1”).

In Patent document 1, a showerhead is configured to spray a reaction gas introduced into a main hole and an auxiliary hole onto the wafer surface through a guide groove.

On the other hand, inside a vacuum chamber used for display manufacturing, a diffuser may be provided to uniformly spray gas onto glass. A display is a non-light emitting device in which liquid crystals are injected between an array substrate and a color filter substrate to obtain an image effect by using the characteristics thereof. The array substrate and the color filter substrate may be manufactured in such a manner that a thin film is repeatedly deposited onto a transparent substrate made of glass or the like, and patterning and etching are followed. In this case, when a reaction material and a source material in a gaseous phase are introduced into the vacuum chamber in a deposition process, introduced gases are passed through the diffuser and deposited onto glass installed on a susceptor to form a film.

One example of the diffuser is disclosed in Korean Patent No. 10-1352923 (hereinafter, referred to as “Patent Document 2”).

In Patent Document 2, a diffuser is disposed in an upper region in the chamber to provide a deposition material onto the surface of a glass substrate.

Fluid passing members, such as the showerhead of Patent Document 1 and the diffuser of Patent Document 2, may be influenced by the temperature inside an enclosed process chamber. When a fluid passing member is under influence by temperature, a temperature deviation may occur in the fluid passing member itself, which may cause deformation to occur. This may cause a problem in that the direction and density of process fluid distribution may not be uniform. In other words, when the fluid passing member is influenced by the temperature inside the process chamber, there may arise a problem in that deformation of a product may occur, which may adversely influence functions of the product.

In an effort to prevent the problem caused when the product is affected by the temperature, an apparatus for controlling temperature of a product is disclosed.

One example of the apparatus for controlling the temperature of the product is disclosed in Korean Patent No. 10-0802667 (hereinafter, referred to as “Patent Document 3”).

In Patent document 3, an electrode plate is disposed in parallel with a susceptor and a temperature control plate in which a heat transfer medium flow path is formed is disposed at a center upper portion of the electrode plate, such that cold heat of refrigerant which flows through the heat transfer medium flow path is supplied to the electrode plate to control the temperature inside a product.

However, Patent Document 3 has a structure in which the heat transfer medium flow path formed by meandering the inside of the temperature control plate has a bent flow path structure, such that the refrigerant introduced from an inlet flows to the vicinity of a central portion of the temperature control plate and then flows to a peripheral portion to be discharged to a heat transfer medium discharge pipe.

Due to such a structure, in Patent Document 3, a temperature deviation between the refrigerant temperature in the inlet and the refrigerant temperature in the discharge pipe may be caused. This may cause a problem in that the temperature inside the product may not be properly controlled because the temperature of the vicinity of the central portion where the refrigerant introduced into the inlet flows first and the temperature of the peripheral portion where the refrigerant flows thereafter are not uniform. As a result, there is a problem that deformation of a product and a functional error thereof may occur due to uniform internal temperature of the product.

The foregoing is intended merely to aid in the understanding of the background of the present invention, and is not intended to mean that the present invention fails within the purview of the related art that is already known to those skilled in the art.

### Documents of Related Art

(Patent document 1) Korean Patent No. 10-0769522

(Patent document 2) Korean Patent No. 10-1352923

(Patent document 3) Korean Patent No. 10-0802667

### SUMMARY OF THE INVENTION

Accordingly, the present invention has been made keeping in mind the above problems occurring in the related art, and an objective of the present invention is to provide a temperature control apparatus capable of uniformly controlling the temperature of a product by reducing a temperature deviation of a temperature control material flowing inside the product.

In order to achieve the above objective, according to one aspect of the present invention, there is provided a temperature control apparatus, including a flow path line being in communication with an inside of a temperature control object; a first operating part coupled to a first end of the flow path line; a second operating part coupled to a second end of the flow path line; and a heat source part supplying heat energy to or depriving the heat energy of a temperature control medium of the flow path line, wherein the temperature control medium controls a temperature of the temperature control object while flowing bidirectionally in the flow path line by operation of the first and second operating parts.

Furthermore, the first and second operating parts may be piston pumps.

Furthermore, an air layer may be provided between an end of each of the piston pumps and the temperature control medium.

Furthermore, the heat source part may include a first heat source part provided on the flow path line between the first operating part and the temperature control object.

Furthermore, the heat source part may include a second heat source part provided on the flow path line between the second operating part and the temperature control object.

Furthermore, the heat source part may be provided on an outside of the flow path line.

The temperature control apparatus may further include: a buffer chamber provided on each of the flow path line between the first operating part and the temperature control object and the flow path line between the second operating part and the temperature control object, and controlling a temperature of the temperature control medium.

Furthermore, the heat source part may be provided inside the buffer chamber.

Furthermore, the flow path line may include: an internal flow path line provided inside the temperature control object; and an external flow path line provided outside the temperature control object, wherein the internal flow path line may include a plurality of branch flow paths.

Furthermore, the plurality of branch flow paths may be arranged in a planar manner.

Furthermore, the plurality of branch flow paths may be arranged vertically.

As described above, the temperature control apparatus according to the present invention has a structure in which the temperature control medium can flow bidirectionally in one flow path line, and the heat source part capable of reducing the temperature deviation occurring at the first end and the second end of the flow path line is provided. Therefore, it is possible to control the temperature control medium, having a uniform temperature to flow bidirectionally in the flow path line inside a product, thereby ensuring uniformity of the temperature of the product.

### BRIEF DESCRIPTION OF THE DRAWINGS

The above and other objectives, features, and other advantages of the present invention will be more clearly understood from the following detailed description when taken in conjunction with the accompanying drawings, in which:

FIG. 1 is a view schematically illustrating a temperature control apparatus according to a first embodiment of the present in

FIG. 2 is a view schematically illustrating a temperature control apparatus according to a second embodiment of the present invention;

FIGS. 3 to 6 are views schematically illustrating various embodiments of a flow path line according to the present invention;

FIG. 7 is a view schematically illustrating a temperature control apparatus according to a third embodiment of the present invention;

FIGS. 8 to 10 are views schematically illustrating various coupling structures of the temperature control apparatus according to the present invention;

FIG. 11 is a plan view illustrating a flow path line according to the coupling structure of FIG. 10; and

FIG. 12 is a view schematically illustrating an embodiment of the flow path line according to the present invention.

### DETAILED DESCRIPTION OF THE INVENTION

Contents of the description below merely exemplify the principle of the invention. Therefore, those of ordinary skill in the art may implement the theory of the invention and invent various apparatuses which are included within the concept and the scope of the invention even though it not clearly explained or illustrated in the description. Furthermore, in principle, all the conditional terms and embodiments listed in this description are clearly intended for the purpose of understanding the concept of the invention, and one should understand that this invention is not limited the exemplary embodiments and the conditions.

The above described objectives, features, and advantages will be more apparent through the following detailed description related to the accompanying drawings, and thus those of ordinary skill in the art may easily implement the technical spirit of the invention.

The embodiments of the present invention will be described with reference to cross-sectional views and or perspective views which schematically illustrate ideal embodiments of the present invention. For explicit and convenient description of the technical content, sizes or thicknesses of films and regions and diameters of holes in the figures may be exaggerated. Therefore, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing.

Wherever possible, the same reference numerals will be used throughout different embodiments and the description to refer to the same or like elements or parts. In addition, the configuration and operation already described in other embodiments will be omitted for convenience.

Hereinafter, exemplary embodiments of the present invention will be described in detail with reference to the accompanying drawings.

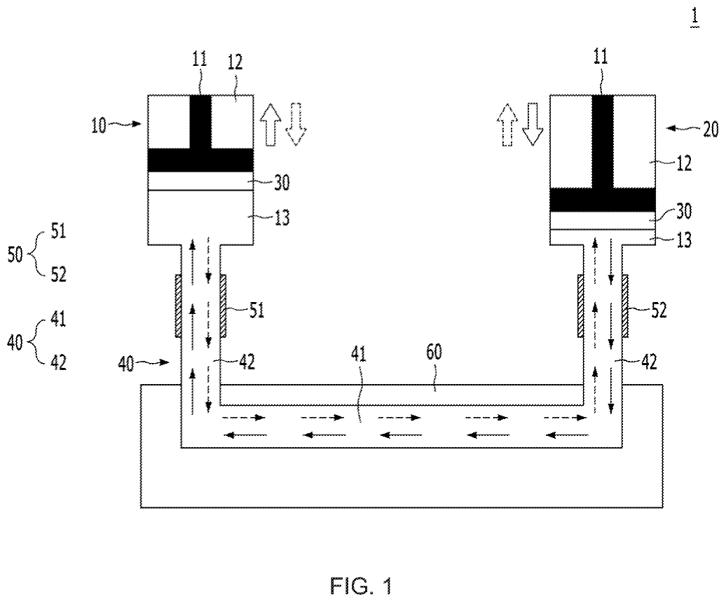

FIG. 1 is a view schematically illustrating a temperature control apparatus 1 according to a first embodiment of the present invention. As illustrated in FIG. 1, the temperature control apparatus 1 includes a flow path line 40 being in communication with an inside of a temperature control object 60, first and second operating parts 10 and 20 coupled to a first end and a second end of the flow path line 40, and a heat source part 50.

The temperature control apparatus 1 according to the present invention having such a configuration can uniformly control the internal temperature of the temperature control object 60. The temperature control object 60 of which the temperature is controlled by the temperature control apparatus 1 may be a diffuser as an example.

In addition, the temperature control object 60 may be a component provided in semiconductor manufacturing process equipment or display manufacturing process equipment to spray a process fluid.

In detail, the semiconductor manufacturing process equipment or the display manufacturing process equipment provided with the temperature control object 60 includes etching equipment, cleaning equipment, heat treatment equipment, ion implantation equipment, sputtering equipment, CVD equipment, or the like which will be described below.

The semiconductor manufacturing process equipment or the display manufacturing process equipment provided with the temperature control object 60 may be etching equipment. In this case, the temperature control object 60 may be a component for supplying a process fluid for an etching process to a workpiece. The etching equipment provided with the temperature control object 60 may be wet etching equipment, dry etching equipment, plasma etching equipment, or reactive ion etching (RIP) equipment.

When the temperature control object 60 is a component provided in the etching equipment as described above, the temperature of the temperature control object 60 may be uniformly controlled by the temperature control apparatus 1 according to the present invention so that deformation may be minimized. This makes it possible to perform a function more effectively in terms of spraying the process fluid, and to reduce a defect rate of a manufactured product in a semiconductor manufacturing process or a display manufacturing process.

The semiconductor manufacturing process equipment or the display manufacturing process equipment provided with the temperature control object 60 may be cleaning equipment. In this case, the temperature control object 60 may be a component for supplying a process fluid for a cleaning process to a workpiece. The cleaning equipment may clean particulate or chemical foreign substances causing defects in a production process using the process fluid sprayed by the temperature control object 60. The cleaning equipment provided with the temperature control object 60 may be a cleaner or a wafer scrubber.

The temperature control object 60 as described above can ensure uniformity of the internal temperature by the temperature control apparatus 1 according to the present invention. This makes it possible to effectively perform a function in terms of spraying the process fluid and to reduce a defective rate of a manufactured product in the semiconductor manufacturing process or the display manufacturing process.

The semiconductor manufacturing process equipment or the display manufacturing process equipment provided with the temperature control object 60 may be heat treatment equipment. The temperature control object 60 may supply a process fluid for a heat treatment process. The heat treatment equipment may apply heat at a high speed to activate dopants implanted by a method such as ion implantation and may form an oxide film, a nitride film, and the like.

The temperature control object 60 provided in the heat treatment equipment as described above may have a uniform internal temperature controlled by the temperature control apparatus 1 according to the present invention. This minimizes product deformation so that the function of spraying process fluid for the heat treatment process can be performed more effectively. As a result, it is possible to obtain an effect of reducing a defect rate of a manufactured product manufactured in the semiconductor manufacturing process or the display manufacturing process.

The semiconductor manufacturing process equipment or the display manufacturing process equipment provided with the temperature control object 60 may be ion implantation equipment. The ion implantation equipment may consciously pressurize impurity atoms (preferably 3 to 5) to give a certain electrical resistance onto the surface of a wafer. In this case, the temperature control object 60 provided in the ion implantation equipment may supply a process fluid for an ion implantation process to a workpiece.

The temperature control object 60 provided in the ion implantation equipment can ensure uniformity of the temperature by the temperature control apparatus 1 according to the present invention, thereby minimizing product deformation. As a result, it is possible to more effectively perform the function of supplying the process fluid in the semiconductor manufacturing process or the display manufacturing process and thus to reduce a defect rate of a manufactured product manufactured through the process.

The semiconductor manufacturing process equipment or the display manufacturing process equipment provided with the temperature control object 60 may be sputtering equipment. In this case, the temperature control object 60 may supply a process fluid for a sputtering process to a workpiece.

The sputtering equipment provided with the temperature control object 60 is a device for forming a metal film on the wafer. The sputtering equipment may form a metal film on the surface of the wafer using a sputter profile.

The temperature control object 60 provided in the sputtering equipment may have a uniform internal temperature controlled by the temperature control apparatus 1 according to the present invention. This makes it possible to minimize product deformation, thereby improving reliability in terms of spraying the process fluid, and reducing a defect rate of a manufactured product manufactured through the semiconductor manufacturing process or the display manufacturing process.

The semiconductor manufacturing process equipment or the display manufacturing process equipment provided with the temperature control object 60 may be CVD equipment. In this case, the temperature control object 60 provided in the CVD equipment as the semiconductor manufacturing process equipment may be a showerhead. Meanwhile, the temperature control object 60 provided in the CVD equipment as the display manufacturing process equipment may be a diffuser.

The CVD equipment provided with the temperature control object 60 may be atmospheric pressure CVD equipment, reduced pressure CVD equipment, plasma CVD equipment, photo-initiated CVD equipment, or MO-CVD equipment. The temperature control object 60 may supply a process fluid for a CVD process to a workpiece.

The temperature control object 60 provided in the CVD equipment as described above may have an internal temperature controlled by the temperature control apparatus 1 according to the present invention to ensure uniformity of the entire product temperature. This makes it possible to minimize product deformation. The temperature control object 60 in which uniformity of the product temperature is ensured can more effectively perform the function of spraying the process fluid in a manufacturing process. As a result, it is possible to obtain an effect of reducing a defect rate of a manufactured product manufactured in the manufacturing process.

The temperature control object 60 of which the temperature is controlled by the temperature control apparatus 1 according to the present invention is not limited to the above configuration, and the present invention may be provided in a variety of temperature control object 60 to achieve the effect of ensuring uniformity of the internal temperature of a product.

Hereinafter, the temperature control apparatus 1 according to the present invention will be described in detail.

As illustrated in FIG. 1, the flow path line 40 of the temperature control apparatus 1 is provided to be in communication with the inside of the temperature control object 60.

The flow path line 40 is a line through which a temperature control medium (liquid or gas) for controlling the temperature of the temperature control object 60 flows. The flow path line 40 may be provided to be in communication with the inside of the temperature control object 60 so that the temperature control medium flows through the inside of the temperature control object 60 to control the temperature thereof.

The flow path line 40 may include an internal flow path line provided. inside the temperature control object 60 and an external flow path line 42 provided outside the temperature control object 60. In this case, the internal flow path line 41 may be a flow path line provided inside the temperature control object 60 to substantially control the temperature of the temperature control object 60 by the flow of the temperature control medium. Meanwhile, the external flow path line 42 may be a flow path line provided outside the temperature control object 60 at a position where the flow direction of the temperature control medium is changed by the operation of the first and second operating parts 10 and 20.

The first end of the flow path line 40 may be coupled to the first operating part 10, while the second end of the flow path line 40 may be coupled to the second operating part 20. In this case, the first and second operating parts 10 and 20 may be piston pumps. However, the first and second operating parts 10 and 20 are not limited to the piston pumps, and include all the operating sources as long as being capable of allowing the temperature control medium flowing along one flow path line to bidirectionally flow.

When the first and second operating parts 10 and 20 are piston pumps, each of the first and second operating parts 10 and 20 may include a piston 11, a first chamber 12, an air layer 30, and a second chamber 13.

The temperature control medium flows in or out of the second chamber 13 of the piston pump. The second chamber 13 is in communication with the flow path line 40 so that the temperature control medium of the flow path line 40 flows in or out of the second chamber 13. When the temperature control medium flows into the second chamber 13, the piston 11 is lifted, and when the temperature control medium flows out of the second chamber 13, the piston 11 is lowered.

The air layer 30 may be provided between the end of the piston 11 and the temperature control medium.

The air layer 30 may be provided between the end of the piston 11 and the temperature control medium to function to block heat such that the piston 11 is not affected by heat of the temperature control medium. In other words, the air layer 30 may perform a function of thermal insulation.

The piston 11 may include a sealing portion at the end thereof. For example, the sealing portion may be an O-ring. Due to the sealing portion provided at the end of the piston 11, air of the air layer 30 can be prevented from leaking.

The first and second operating parts 10 and 20 are coupled to the first end and the second end of the flow path line 40, respectively, so that the first and second operating parts 10 and 20 may allow the temperature control medium flowing in the flow path line 40 to bidirectionally flow in one flow path line 40. Since the first and second operating parts 10 and 20 are provided as piston pumps, continuous bidirectional flows may be generated only by alternating operation of the first and second operating parts 10 and 20.

In the description with reference to FIG. 1, for convenience, it is described that the left side in the drawing of FIG. 1 is the first end of the flow path line 40 and the right side in the drawing is the second end of the flow path line 40. Accordingly, an operating part coupled to the external flow path line 42 of the flow path line 40 on the left side in the drawing of FIG. 1 may be the first operating part 10, and an operating part coupled to the external flow path line 42 on the right side in the drawing of FIG. 1 may be the second operating part 20.

As illustrated in FIG. 1, the first and second operating parts 10 and 20 may be coupled to ends of the respective external flow path lines 42 and may be provided in a structure that operates above the temperature control object 60.

FIG. 1 illustrates a state in which the temperature control medium flows by the operation of the second operating part 20. As illustrated in FIG. 1, when the second operating part 20 is lowered, the temperature control medium may flow along the flow path line 40 toward the first operator 10. Due to the temperature control medium flowing toward the first operating part 10, the piston 11 of the first operating part 10 is lifted. The solid arrow illustrated in FIG. 1 indicates the flow direction of the temperature control medium that flows by the lowering operation of the second operating part 20.

Since the first and second operating parts 10 and 20 are coupled to one flow path line 40, the piston 11 of the first operating part 10 may be rifted in cooperation with the lowering operation of the piston 11 of the second operating part 20. The first operating part 10 may be operated such that the temperature control medium flows toward the second operating part 20. The dotted arrow illustrated in FIG. 1 indicates the flow direction of the temperature control medium that flows by the lowering operation of the first operating part 10.

The temperature control medium which starts to flow from the external flow path line 42 on the left side in the drawing of FIG. 1 by the operation of the first operating part 10 may flow along the internal flow path line 41 through the external flow path line 42 on the left side, and then flow into the second chamber 13 of the second operating part 20 through the external flow path line 42 on the right side in the drawing of FIG. 1 to allow the piston 11 of the second operating part 20 to be lifted. Meanwhile, the temperature control medium flowing out of the second chamber 13 of the second operating part 20 may flow along the internal flow path line 41 through the external flow path line 42 on the right side in the drawing of FIG. 1, and then flow into the second chamber 13 of the first operating part 10 through the external flow path line 42 on the left side in the drawing of FIG. 1 to allow the piston 11 of the first operating part 10 to be lifted.

As described above, the present invention is characterized in that the temperature control medium can bidirectionally flow in the flow path line 40 by the alternating operation of the first and second operating parts 10 and 20. Due thereto, an inlet side flow path line for the temperature control object 60 may be an outlet side flow path line.

Unlike the present invention, when the temperature control medium flows unidirectionally only from a first end to a second end of any one direction by the operation of any one of the first and second operating parts 10 and 20, a difference may occur in the temperatures of the temperature control medium at the first end and the second end.

Referring to FIG. 1, when the temperature control medium starts to flow by the operation of the first operating part 10 at the first end of the flow path line 40 to which the first operating part 10 is coupled and flows toward the second operating part 20, a difference may occur between the temperature of the temperature control medium that starts to flow at the first end of the flow path line 40 and the temperature of the temperature control medium when reaching the second operating part 20 at the second end of the flow path line 40.

On the contrary, when the temperature control medium starts to flow by the operation of the second operating part 20 at the second end of the flow path line 40 to which the second operation unit 20 is coupled and flows toward the first operating part 10, a difference may also occur between the temperature of the temperature control medium that starts to flow at the second and of the flow path line 40 and the temperature of the temperature control medium when reaching the first operating part 10 at the first end of the flow path line 40.

When the temperature control medium flows from the first end of the flow path line 40 to the second end by the operation of any one operating part, the present invention may be provided with the heat source part 50 in order to reduce a temperature difference occurring at the first end and the second end of the flow path line 40.

The heat source part 50 may serve to supply heat energy to or deprive heat, energy from the temperature control medium flowing along the flow path line 40. The heat source part 50 may be provided on the flow path line 40.

In this case, the heat source part 50 may be provided at a portion where a large temperature difference of the temperature control medium flowing along the flow path line 40 occurs in other words, when the temperature control medium flows from the first end of the flow path line 40 to the second end as described above, a difference may occur between the temperature of the temperature control medium at the first end and the temperature of the temperature control medium at the second end. This is a difference that occurs due to a change in temperature due to heat being supplied to or deprived from the temperature control object 60 while the temperature control medium flowing along the flow path line 40 flows unidirectionally. Therefore, the heat source part 50 may be provided at each of the first end and the second end of the flow path line 40 to reduce the temperature difference at the first end and the second end of the flow path line 40 such that the temperature of the temperature control medium flowing along the flow path line 40 may be controlled, thereby making it possible to uniformly maintain the temperature inside the temperature control object 60.

Referring to FIG. 1, the heat source part 50 may be provided on the flow path line 40 located between the first operating par 10 and the temperature control object 60. In addition, the heat source part 50 may be provided on the flow path line 40 located between the second operating part 20 and the temperature control object 60. The flow path line 40 between the first operating part 10 and the temperature control object 60 and the flow path line 40 between the second operating part 20 and the temperature control object 60 may be the external flow path lines 42 provided outside the temperature control object 60.

In other words, the heat source part 50 may be provided each of on the external flow path line 42 on the left side and the external flow path line 42 on the right side. As described above, the temperature difference of the temperature control medium may occur at the first end and the second end of the flow path line 40. The external flow path lines 42 are flow path lines provided outside the temperature control object 60 and may be structured in a form, provided at the first end and the second end of the flow path line 40. Therefore, the heat source part 50 provided at each of the end and the second end of the flow path line 40 may be structured in a form provided on each of the external flow path line 42 on the left side and the external flow path line 42 on the right side.

The heat source part 50 may be comprised of a first heat source part 51 provided on the external flow path line 42 on the left side and a second heat source part 52 provided on the external flow path line 42 on the right side.

As illustrated in FIG. 1, the first heat source part 51 may be provided on the external flow path line 42 on the left side, i.e., on the flow path line 40 between the first operating part 10 and the temperature control object 60. In addition, the second heat source part 52 may be provided on the external flow path line 42 on the right side, i.e., on the flow path line 40 between the second operating part 20 and the temperature control object 60. Due to the heat source part 50 having such a structure, the temperature of the temperature control medium may be controlled at the first end and the second end of the flow path line 40. As a result, it is possible to reduce the temperature difference of the temperature control medium at the first end and the second end of the flow path line 40.

As illustrated in FIG. 1, the heat source part 50 may be provided on the outside of the flow path line 40.

The heat source part provided on the outside of the flow path line 40 may be a heating wire, a heater jacket, or a hot air blower capable of supplying heat energy to the temperature control medium, but is not limited thereto. In addition, the heat source part 50 may be a cooling wire, a cooling jacket, or a cold air blower capable of depriving heat energy from the temperature control medium, but is not limited thereto. The heat source part 50 may be provided in a configuration suitable for controlling the temperature of the temperature control medium.

The heat source part 50 as described above may control the temperature of the flow path line 40 on the outside of the flow path line 40 to control the temperature of the temperature control medium flowing along the flow path line 40. In other words, the heat source part 50 provided on the outside of the flow path line may control the temperature of the flow path line 40 to indirectly control the temperature of the temperature control medium.

As described above, the present invention is characterized in that the first and second operating parts 10 and 20 are coupled to one flow path line 40, thereby making it possible to allow the temperature control medium to bidirectionally flow in the flow path line 40 by the alternating operation of the first and second operating parts 10 and 20. In this case, the heat source part 50 allows the temperature control medium to reciprocately flow along the flora path line 40 at a uniform temperature. The temperature control medium of which the temperature is controlled as above can control the temperature of the temperature control object 60 while flowing bidirectionally along the flow path line 40 by the alternating operation of the first and second operating parts 10 and 20.

In the related art, as a temperature control material flows along a flow path, temperature is changed, causing a difference in the temperature at an inlet and the temperature at an outlet. Due thereto, there is a problem that it is difficult to ensure uniformity of temperature around the inlet and the outlet inside a product.

However, in the present invention, due to a structure in which the heat source part 50 is provided on each of the external flow path lines 42 of the flow path line 40 and the first and second operating parts 10 and 20 are coupled to one flow path line 40, it is possible to allow the temperature control medium of which the temperature is controlled by the heat source part 50 to flow bidirectionally, thereby reducing the temperature difference at the first end and the second end of the flow path line 40. As a result, it is possible to uniformly control the internal temperature of the temperature control object 60 while maintaining the temperature of the temperature control medium flowing along the flow path line 40 uniformly.

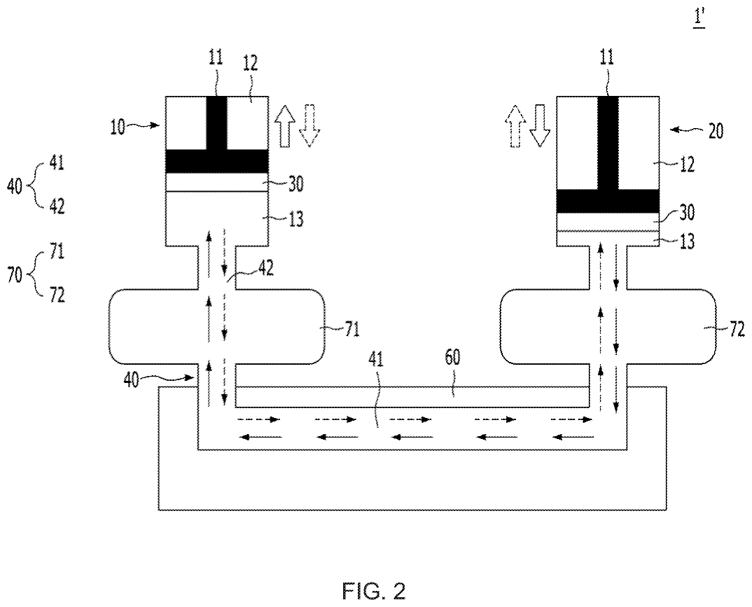

Hereinafter, a temperature control apparatus 1′ according to a second embodiment of the present invention will be described with reference to FIG. 2. The second embodiment differs from the first embodiment in that a buffer chamber 70 is provided. In the second embodiment, characteristic components will be described in comparison with the first embodiment, and descriptions of the same or similar components as the first embodiment will be omitted.

As illustrated in FIG. 2, the temperature control apparatus 1′ includes a flow path line 40 being in communication an inside of a temperature control object 60, a first operating part 10 coupled to a first end of the flow path line 40, a second operating part 20 coupled to a second end of the flow path line 40, and the buffer chamber 70.

The buffer chamber 70 may be comprised of a first buffer chamber 71 provided on the flow path line 40 between the first operating part 10 and the temperature control object 60, and a second buffer chamber 72 provided on the flow path line 40 between the second operating part 20 and the temperature control object 60.

As illustrated in FIG. 2, the first buffer chamber 71 may be provided on. an external flow path line 42 on the left side, i.e., on the flow path line 40 between the first operating part 10 and the temperature control object 60. In addition, the second buffer chamber 72 may be provided on an external flow path line 42 on the right side, i.e., on the flow path line 40 between the second operating part 20 and the temperature control object 60. The buffer chamber 70 as described above may be structured in a form provided on the external flow path lines 42, in communication with the external flow path lines 42. Due to the communication with the external flow path lines 42, the buffer chamber 70 may be in communication with the entire flow path line 40.

A heat source part may be provided inside or outside the buffer chamber 70. The buffer chamber 70 may control the temperature of a temperature control medium flowing along the flow path line 40.

In this case, the volume of the buffer chamber 70 may be equal to or preferably greater than the volume of the flow path line 40. Since the buffer chamber 70 according to the second embodiment is comprised of the first buffer chamber 71 and the second buffer chamber 72, each of the volumes of the first buffer chamber 71 and the second buffer chamber 72 may be equal to or preferably greater than ½ of the volume of the flow path line 40. The buffer chamber 70 may be provided in the above volume to more effectively perform a function of temperature control.

The temperature control medium may flow in the buffer chamber that is in communication with the flow path line 40 while flowing along the flow path line 40 so that the temperature of the temperature control medium may be controlled by the heat source part provided inside the buffer chamber 70. The buffer chamber 70 may be structured in a form of directly controlling the temperature of the temperature control medium flowing inside the buffer chamber 70 by the use of the heat source part provided inside or outside the buffer chamber 70.

The dotted arrow illustrated in FIG. 2 indicates the flow direction of the temperature control medium flowing by the operation of the first operating part 10, and the solid arrow indicates the flow direction of the temperature control medium flowing by the operation of the second operating part 20.

In the second embodiment, the buffer chamber 70 having the heat source part 50 therein is provided to be in communication with the external flow path lines 42 of the flow path line 40, thereby making it possible to allow the temperature control medium flowing bidirectionally along one flow path line 40 to flow in the buffer chamber 70. The temperature of the temperature control medium may be controlled at the first end and the second end of the flow path line 40 while the temperature control medium flows inside the buffer chamber 70.

Due to the above structure, it is possible to reduce a temperature difference of the temperature control medium occurring at the first end and the second end of the flow path line 40. As a result, the temperature control medium can control the temperature of the temperature control object 60 by flowing the inside of the temperature control object 60 at a uniform temperature.

The flow path line 40 constituting the present invention, along which the temperature control medium flows, may be comprised of an internal flow path line 41 provided inside the temperature control object 60 and the external flow path lines 42 provided outside the temperature control object 60, and may include a plurality of branch flow paths 41a and 41b and. 41c formed at the internal flow path line 41.

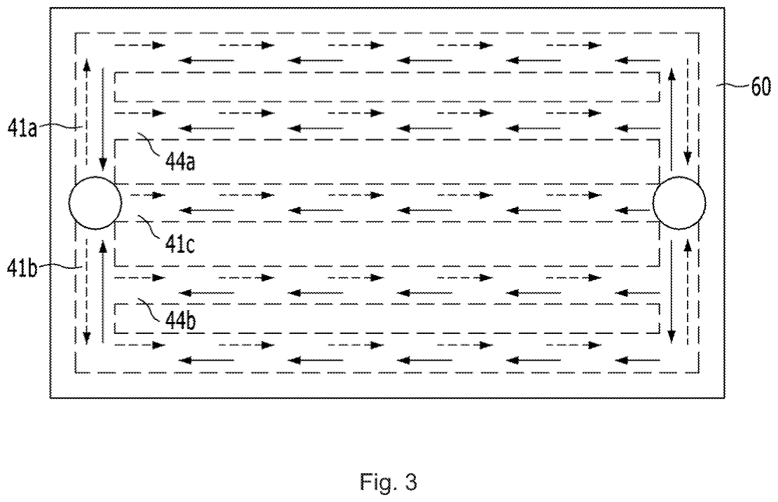

Hereinafter, various embodiments of the flow path line constituting the present invention will be described with reference to FIGS. 3 to 6.

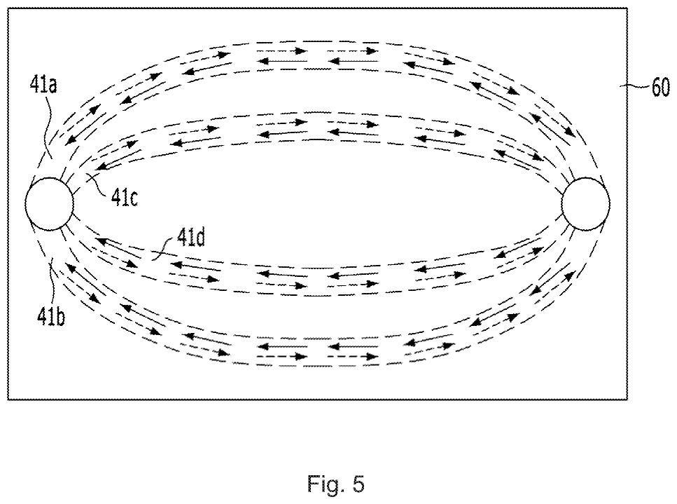

A plurality of branch flow paths which are branched from a common flow path 43 of the internal flow path line 41 may be arranged in a planar manner. FIGS. 3 and 5 are views illustrating the plurality of branch flow paths arranged in a planar manner.

The internal flow path line 41 may include the common flow path 43 and a branch flow path branched from the common flow path 43. In this case, the branch flora path may be provided as a plurality of branch flow paths.

In FIGS. 3 and 5, arrangement positions of the first and second operating parts 10 and 20 are exemplarily illustrated, and thus the present invention is not limited thereto.

First, a planar arrangement structure of the branch flow paths will be described with reference to FIG. 3. A circular cross-section illustrated on the left side in the drawing of FIG. 3 may be a flow path line connected to the first operating part 10, and a circular cross-section illustrated on the right side in the drawing of FIG. 3 may be a flow path line connected to the second operating part 20.

As illustrated in FIG. 3, with respect to the flow path line connected to the first operating part 10, a first branch flow path 41a is provided on the upper side in the drawing of FIG. 3, a second branch flow path 41b is provided on the lower side in the drawing, and a third branch flow path 41c is provided on the same horizontal line as the flow path line connected to the first operating part 10. In addition, as illustrated in FIG. 3, each of the branch flow paths may include an additional branch flow path additionally branched from the branch flow path, such that a plurality of additional branch flow paths may be provided. As illustrated in FIG. 3, first additional branch flow path 44a branched from the first branch flow path 41a may be provided above the third branch flow path 41c. In add on, a second additional branch flow path 44b branched from the second branch flow path 41b may be provided below the third branch flow path 41c.

In this case, since the first and second operating parts 10 and 20 are coupled to one flow path line 40, the first, second, and third branch flow paths 41a, 41b, and 41c and the first and second additional branch flow paths 44a and 44h as described above may be connected to the flow path line connected to the second operating part 20.

The number of the branch flow paths illustrated in FIG. 3 is exemplarily illustrated, and thus the present invention is not limited thereto.

When the branch flow paths are arranged in the above configuration, the temperature control medium flowing along the flow path line 40 by the operation of the first and second operating parts 10 and 20 may be split into the respective branch flow paths. The temperature control medium may flow bidirectionally in the flow path line 40 by the alternating operation of the first and second operating parts 10 and 20, so that the temperature control medium may flow bidirectionally even in the branch flow paths.

In FIG. 3, the dotted arrow indicates the flow direction of the temperature control medium flowing by the operation of the first operating part 10, and the solid arrow indicates the flow direction of the temperature control medium flowing by the operation of the second operating part 20.

A heat source part 50 provided on each of the external flow path lines may serve to reduce a temperature difference of the temperature control medium at the first end and the second end of the flow path line 40. This allows the temperature control medium to flow along the branch flow paths in a controlled state at a uniform temperature.

The temperature control medium may flow through the entire horizontal area of the temperature control object 60 through the branch flow paths, thereby making it possible to ensure uniformity of the temperature of the temperature control object 60.

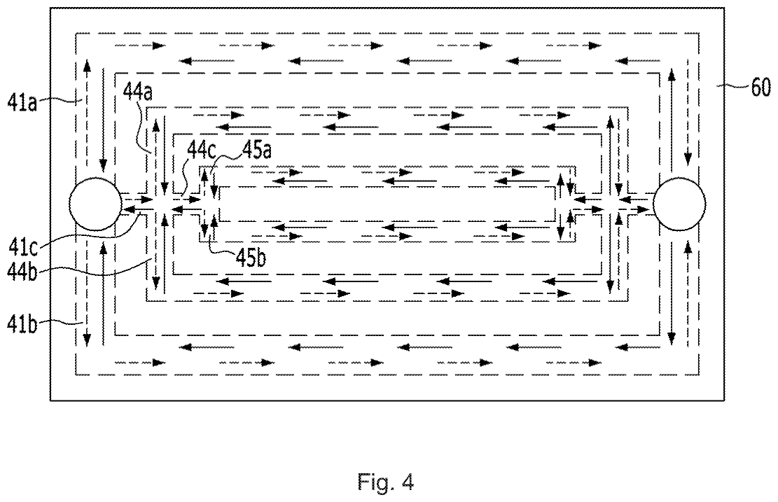

FIG. 4 is a plan view illustrating a structure of a flow path line 40 arranged in a structure different from that of FIG. 3. A circular cross-section illustrated on the left side in the drawing of FIG. 4 may be a flow path line connected to the first operating part 10, and a circular cross-section illustrated on the right side in the drawing of FIG. 4 may be a flow path line connected to the second operating part 20.

As illustrated in FIG. 4, a first branch flow path 41a is provided on the upper side in the drawing with respect to the flow path line connected to the first operating part 10, and a second branch flow path 41b is provided on the lower side in the drawing with respect to the flow path line connected to the first operating part 10. In addition, a third branch flow path 41c is provided on the same horizontal line as the flow path line connected to the first operating part 10.

The flow path line may be configured in a structure in which an additional branch flow path is provided through the third branch flow path 41c. Referring to FIG. 4, a first additional branch flow path 44a may be provided at an end of the third branch flow path 41c on the upper side in the drawing of FIG. 4, and a second additional branch flow path 44b may be provided at the end of the third branch flow path 41c on the lower side in the drawing. The first and second additional branch flow paths 44a and 44b are branched from the end of the third branch flow path 41c upwardly and downwardly of the third branch flow path 41c. Therefore, the third branch flow path 41c may function as a common flow path 43 connecting the first and second branch flow paths 44a and 44b to the first and second branch flow paths 41a and 41b.

The first and second branch flow paths 44a. and 44b may have a shorter length than the first and second branch flow paths 41a and 41b. In addition, the third branch flow path 41c is a flow path line provided to form a structure for communicating the first and second additional branch flow paths 44a and 44b with the first and second branch flow paths 41a and 41b. Due thereto, the length of the third branch flow path 41c may have a shorter length than other branch flow paths (e.g., the first and second branch flow paths 41a and 41b and the first and second additional branch flow paths 44a and 44b).

A third additional branch flow path 44c may be provided to be in communication with the first and second additional branch flow paths 44a and 44b on the same horizontal line in the drawing of FIG. 4) as the third branch flow path 41c. The third additional branch flow path 44c may be provided on the same horizontal line (in the drawing of FIG. 4) as the third branch flow path 41c, and may be branched between the first and second additional branch flow paths 44a and 44b. A branch flow path may be additionally provided again at the third additional branch flow path 44c. A third-first additional branch flow path 45a is provided at an end of the third additional branch flow path 44c on the upper side in the drawing of FIG. 4, and a third-second additional branch flow path 45b is provided at the end of the third additional branch flow path 44c on the lower side in the drawing.

The third-first additional branch flow path 45a and the third-second additional branch flow path 45b may have shorter lengths than the first and second additional branch flow paths 44a and 44b. In addition, the third additional branch flow path 43c is a flour path line provided to form a structure for communicating the third-first additional branch flow path 45a and the third-second additional branch flow path 45b with the first and second additional branch flow paths 44a and 44b. Due thereto, like the above-described third branch flow path 41c, the third additional branch flow path 43c may have a shorter length than other branch flow paths (e.g., the first and second branch flow paths 41a and 41b, the first and second additional branch flow paths 44a and 44b, and the third-first and third-second additional branch flow paths 45a and 45b).

In this case, since the first and second operating parts 10 and 20 are coupled to one flow path line 40, the branch flow paths having the above configuration may be connected to the flow path line connected to the second operating part 20. The number of the branch flow paths illustrated in FIG. 4 is exemplarily illustrated, and thus the present invention is not limited thereto.

Due to such a structure, the temperature control medium flowing bidirectionally by the alternating operation of the first and second operating parts 10 and 20 can uniformly flow through the entire inside of the temperature control object 60 along the branch flow paths.

The dotted arrow illustrated in FIG. 4 indicates the flow direction of the temperature control medium flowing by the operation of the first operating part 10, and the solid arrow indicates the flow direction of the temperature control medium flowing by the operation of the second operating part 20.

As described above, the present invention is characterized in that the additional branch flow paths that are branched from each branch flow path are provided and the lengths of the additional branch flow paths are gradually shortened, thereby allowing the temperature control medium to flow through the entire internal horizontal area of the temperature control object 60. Due to such a structure, it is possible to uniformly control the temperature of the temperature control object 60.

FIG. 5 is a plan view illustrating a structure in which a flow path line 40 is provided in a curved form.

A circular cross-section illustrated on the left side in the drawing of FIG. 5 may be a flow path line connected to the first operating part 10, and a circular cross-section illustrated on the right side in the drawing of FIG. 5 may be a flow path line connected to the second operating part 20. In this case, arrangement positions of the first and second operating parts 10 and 20 are exemplarily illustrated, and thus the present invention is not limited thereto.

As illustrated in FIG. 5, each branch flow path may be provided in an arc form and has a substantially elliptical cross-section so that branch flow paths may be arranged in a curved form on the upper and lower sides with respect to the first and second operating parts 10 and 20.

The dotted arrow illustrated in FIG. 5 indicates the flow direction of the temperature control medium flowing by the operation of the first operating part 10, and the solid arrow indicates the flow direction of the temperature control medium flowing by the operation of the second operating part 20.

As illustrated in FIG. 5, the branch flow paths may be branched in a curved form. A first branch flow path 41a may be provided on the upper side in the drawing of FIG. 5 with respect to the flow path line connected to the first operating part 10, and a second branch flow path 41b may be provided on the lower side in the drawing with respect to the flow path line connected to the first operating part 10. The first and second branch flow paths 41a and 41b may be formed to have the largest perimeter length along the inner perimeter of the temperature control object 60.

A third branch flow path 41c and a fourth branch flow path 41d are provided inside the first and second branch flow paths 41a and 41b. The third and fourth branch flow paths 41c and 41d may be branched from the same common line as a common line where the first and second branch flow paths 1a and 41b are branched, with a smaller perimeter length than the first and second branch flow paths 41a and 41b. In this case, the third branch flow path 41c and the fourth branch flow path 41d may be provided to be adjacent to the first branch flow path 41a and the second branch flow path 41b, respectively, so that the third branch flow path 41c may be provided above the fourth branch flow path 41d.

In this case, since the first and second operating parts 10 and 20 are coupled to one flow path line 40, the branch flow paths having the above configuration may be connected to the flow path line connected to the second operating part 20. The number of the branch flow paths illustrated in FIG. 5 is exemplarily illustrated, and thus the present invention is not limited thereto.

Due to the above structure, the temperature control medium can uniformly flow an inner central portion and an inner peripheral portion of the temperature control object 60. As a result, the internal temperature of the temperature control object 60 can be made uniform.

Meanwhile, a plurality of branch flow paths may be arranged vertically.

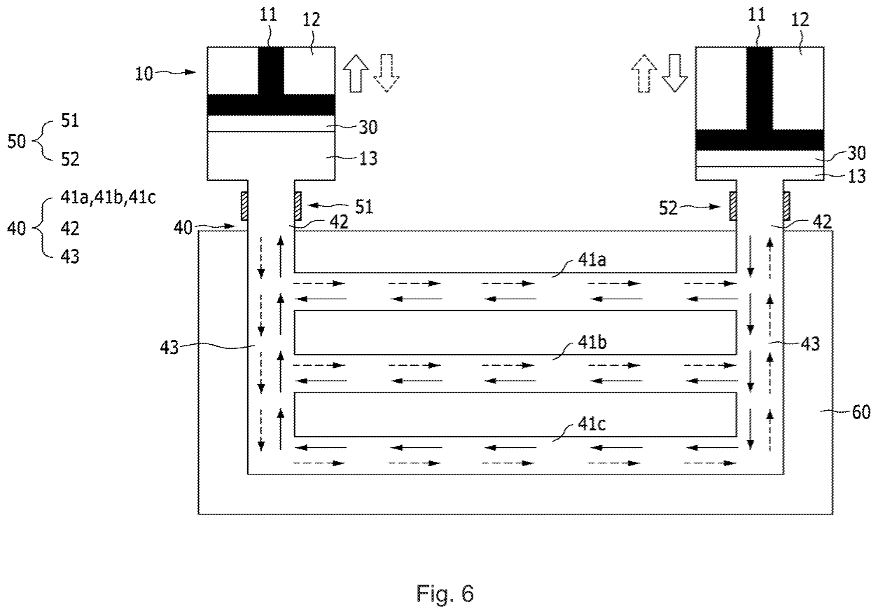

FIG. 6 is a view schematically illustrating the plurality of branch flow paths arranged vertically.

As illustrated in FIG. 6, the plurality of branch flow paths may be vertically arranged in a depth direction of the temperature control object 60. The branch flow paths may have a structure vertically branched from a common flow path 43 in the depth direction. Due to the above structure, the branch flow paths may be arranged in a stacked form with a predetermined interval between the branch flow paths.

In detail, a branch flow path provided on the uppermost side in the drawing of FIG. 6 among the branch flow paths branched from the common flow path 43 may be a first, branch flow path 41a, a branch flow path provided below the first branch flow path 41a at a location adjacent to the first branch flow path 41a. may be a second branch flow path 41b, and a branch flow path provided below the second branch flow path 41b at a location adjacent to the second branch flow path 41b may be a third branch flow path 41c.

The first, second, and third branch flow paths 41a, 41b, and 41c may be arranged at an interval from each other to form a structure in which the third branch flow path 41c, the second branch flow path 41b, and the second branch flow path 41c may be sequentially stacked with an interval therebetween with respect to the lower side in the drawing of FIG. 6.

An operating part illustrated on the left side in the drawing of FIG. 6 may be the first operating part 10, and an operating part illustrated on the right side in the drawing of FIG. 6 may be the second operating part 20. Arrangement of the first and second operating parts 10 and 20 is illustrated as one example, and thus W the present invention is not limited thereto. In addition, the dotted arrow illustrated in FIG. 6 indicates the flow direction of the temperature control medium flowing by the operation of the first operating part 10, and the sold arrow indicates the flow direction of the temperature control medium flowing by the operation of the second operating part 20.

Since an internal flow path line 41 has a structure in which the plurality of branch flow paths are arranged vertically, it is possible to uniformly control the internal temperature of the temperature control object 60 in consideration of the depth thereof.

The temperature control medium flowing along the flow path line 40 with reference to FIGS. 3 to 6 is in a state in which a temperature deviation is reduced by the heat source part 50 and thus can flow inside the temperature control object 60 while maintaining a uniform temperature, thereby making it possible to ensure uniformity of the internal temperature of the temperature control object 60.

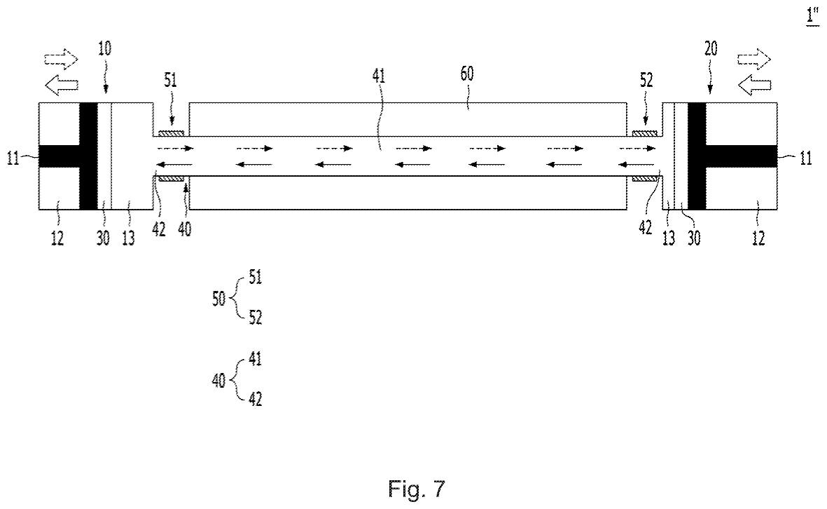

FIG. 7 is a view schematically illustrating a temperature control apparatus 1″ according to a third embodiment of the present invention. The third embodiment differs from the first embodiment in that first and second operating parts 10 and 20 are coupled to a first end and a second end of a flow path line 40 but coupled to the side surface of a temperature control object 60.

As illustrated in FIG. 7, the temperature control apparatus 1″ includes the flow path line 40 being in communication an inside of the temperature control object 60, the first operating part 10 coupled to the first end of the flow path line 40, the second operating part 20 coupled to the second end of the flow path line 40, and a heat source part 50.

As illustrated in FIG. 7, the flow path line 40 may be provided in a straight line form in a horizontal direction to horizontally pass through the inside of the temperature control object 60.

The operating parts may be coupled to the first end and the second of the flow path line 40. When the left side of the flow path line 40 in the drawing of FIG. 7 is referred to as the first end of the flow path line 40, an operating part illustrated on the left side in the drawing of FIG. 7 may be the second operating part 20. In this case, arrangement positions of the first and second operating parts 10 and 20 are exemplarily illustrated, and thus the present invention is not limited thereto.

The first and second operators 10 and 20 may be coupled to end portions of opposite side surfaces of the flow path line 40, respectively, so as to allow a temperature control medium to flow bidirectionally inside the temperature control object 60. As illustrated in FIG. 7, when the first and second operating parts 10 and 20 are coupled to the side surfaces of the flow path line 40, the temperature control medium may flow in the flow path line in such a manner that the flow direction thereof may be determined by alternating operation of the first and second operating parts 10 and 20 and thus the temperature control medium may flow bidirectionally in the flow path line 40.

The dotted arrow illustrated in FIG. 7 indicates the flow direction of the temperature control medium flowing by the operation of the first operating part 10, and the solid arrow indicates the flow direction of the temperature control medium flowing by the operation of the second operating part 20.

In the third embodiment referring to FIG. 7, the heat source part 50 is illustrated aa being provided on the outside of the flow path line 40. However, the third embodiment may be configured to include a buffer chamber 70 in which the heat source part 50 is provided, to control the temperature of the temperature control medium.

The temperature control apparatus 1 according to the present invention may be provided in a structure in which a plurality of temperature control apparatuses are coupled to each other.

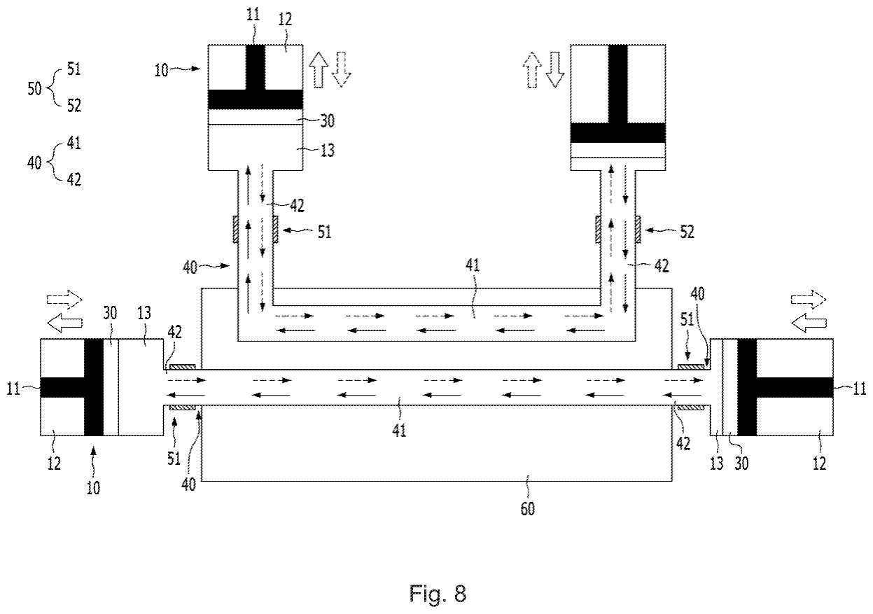

FIGS. 8 to 10 are views schematically illustrating various coupling structures of the temperature control apparatus 1 according to the present invention. In this case, although a heat source part 50 is illustrated as being provided on the outside of each flow path line 40 in FIGS. 8 to 10, this is illustrated as one example. Accordingly, the provision form of the heat source part 50 is not limited thereto. For example, each temperature control apparatus 1 illustrated in FIGS. 8 to 10 may include a buffer chamber 70 in which the heat source part is provided, to form a structure in which a plurality of temperature control apparatuses are coupled to each other.

First, FIG. 8 is a view illustrating a structure in which the temperature control apparatus 1 of the first embodiment and the temperature control apparatus 1″ of the third embodiment are provided and coupled to each other. As illustrated in FIG. 8, the temperature control apparatus 1 of the first embodiment having a structure in which the first and second operating parts 10 and 20 operate above the temperature control object 60, and the temperature control apparatus 1″ of the third embodiment having a structure in which the first and second operating parts 10 and 20 operate at the sides of the temperature control object 60 are configured such that the respective internal flow path lines 41 thereof are provided inside the temperature control object 60.

Two operating parts illustrated on the left side in the drawing of FIG. 8 may be the first operating parts 10, and two operating parts illustrated on the right side in the drawing may be the second operating parts 20. In this case, the dotted arrow indicates the flow direction of the temperature control medium flowing by the operation of the first operating parts 10, and the solid arrow indicates the flow direction of the temperature control medium flowing by the operation of the second operating parts 20.

Due to the above configuration, it is possible to uniformly control the internal temperature of the temperature control object in consideration of the depth thereof, without requiring provision of a plurality of branch flow paths 41a and 41b and 41c arranged vertically.

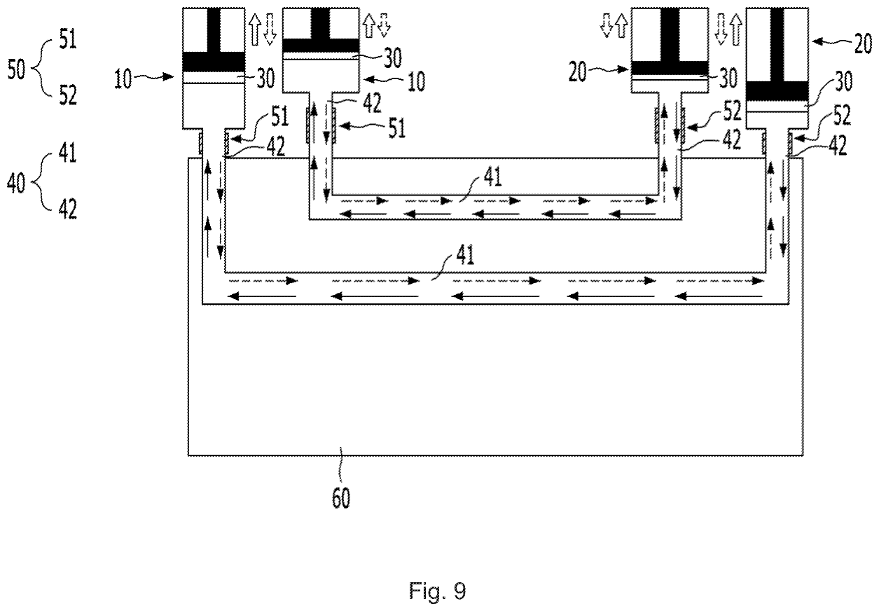

FIG. 9 is a view illustrating a structure in which the temperature control apparatus 1 of the first embodiment having a structure in which the first and second operating parts 10 and 20 operate above the temperature control object 60 is provided as a plurality of temperature control apparatuses that are coupled to each other.

As illustrated in FIG. 9, the temperature control apparatuses 1 of the first embodiment may be configured such that the respective internal flow path lines 41 thereof provided inside the temperature control object 60 may have different horizontal lengths.

Referring to FIG. 9, a temperature control apparatus 1 including an internal flow path line 41 having a relatively long horizontal length among the internal flow path lines 41 provided inside the temperature control object 60 may be a first temperature control apparatus. In addition, a temperature control apparatus 1 including an internal flow path line 41 having a horizontal length shorter than that of the internal flow path line 41 of the first temperature control apparatus may be a second temperature control apparatus.

In this case, two operating parts illustrated on the left side in the drawing of FIG. 9 may be first operating parts 10, and two operating parts illustrated on the right side in the drawing may be second operating parts 20. In addition, the dotted arrow indicates the flow direction of the temperature control medium flowing by the operation of the first operating parts 10, and the solid arrow indicates the flow direction of the temperature control medium flowing by the operation of the second operating parts 20.

As illustrated in FIG. 9, when the plurality of temperature control apparatus 1 in which the internal flow path lines 41 have different lengths are coupled to each other, an arrangement structure in which the second temperature control apparatus is disposed above the first temperature control apparatus and the second temperature control apparatus is disposed inside the first temperature control apparatus may be formed.

Due to the above structure, tine temperature control apparatuses 1 can uniformly control the internal temperature of the temperature control object 60 in consideration of the depth thereof, and uniformly control the temperature of central and peripheral portions of the temperature control object 60.

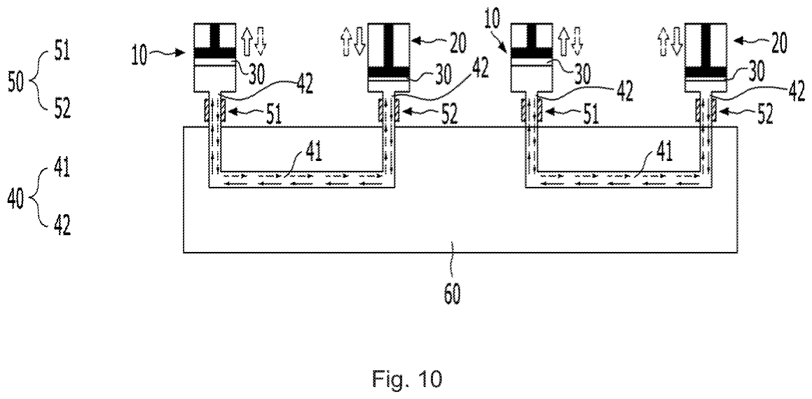

FIG. 10 is a view illustrating a structure in which the temperature control apparatus 1 of the first embodiment having a structure in which the first and second operating parts 10 and 20 operate above the temperature control object 60 is provided as a plurality of temperature control apparatuses that are coupled to each other. While the coupling structure illustrated in FIG. 9 described above is a structure in which the plurality of temperature control apparatuses 1 including the internal flow path lines 41 having different lengths are provided and arranged vertically, the coupling structure illustrated in FIG. 10 may be a structure in which a plurality of temperature control apparatuses 1 configured such that the lengths of the internal flow path lines 41 and the conditions of all the configurations are the same are provided and arranged horizontally.

Operating parts corresponding to the first and third ones from the left side in the drawing of FIG. 10 in one temperature control apparatus 1 may be first operating parts 10, and operating parts corresponding to the second and fourth ones from the right side in the drawing may be second operating parts 20. However, the arrangement of the operating parts is not limited thereto. In addition, the dotted arrow illustrated in FIG. 10 indicates the flow direction of the temperature control medium flowing by the operation of the first operating parts 10, and the solid arrow indicates the flow direction of the temperature control medium flowing by the operation of the second operating parts 20.

The coupling structure as illustrated in FIG. 10 may be formed in the case of uniformly controlling the internal temperature of a temperature control object 60 having a relatively large horizontal area. Alternatively, the case where the temperature control object 60 having a relatively large horizontal area is divided into several zones to control each of the divided zones at different temperatures may be also possible.

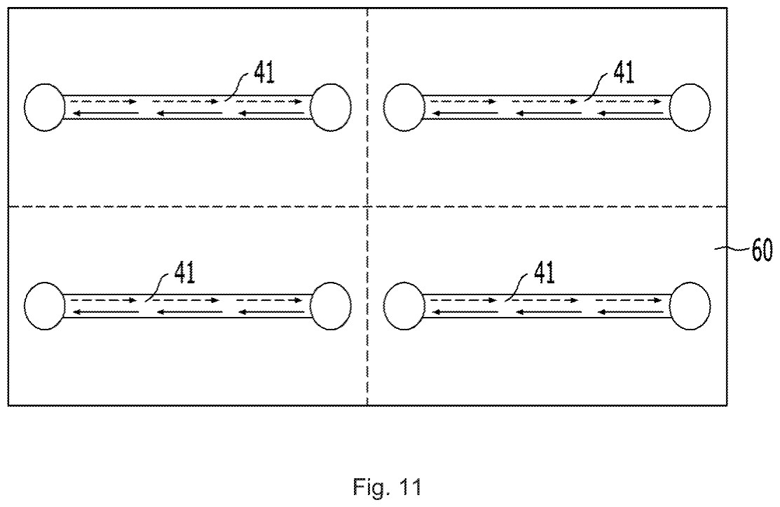

A description will be given with reference to FIG. 11. FIG. 11 is a plan view illustrating a flow path line 40 according to the coupling structure illustrated in FIG. 10. In FIG. 11, as an example, the temperature control object 60 is divided into four zones, and each of the zones is provided with the temperature control apparatus 1. The structure illustrated in FIG. 11 is exemplary, and thus the number of the division zones of the temperature control object 60 and the arrangement of the temperature control apparatuses 1 are not limited thereto.

A circular cross-section of illustrated on the left side in the drawing of FIG. 11 in each of the zones may be a flow path line connected to the first operating part 10, and a circular cross-section illustrated on the right side in the drawing may be a flow path line connected to the second operating part 20. In this case, the dotted arrow illustrated in FIG. 11 indicates the flow direction of the temperature control medium flowing by the operation of the first operating part 10, and the solid arrow indicates the flow direction of the temperature control medium flowing by the operation of the second operating part 20.

The temperature control apparatuses 1 located in the respective zones of the temperature control object 60 may uniformly control the temperatures in all zones by setting the same temperature conditions of the heat source parts 50. As a result, the internal temperature of the entire temperature control object 60 can be made uniform.

Meanwhile, the temperature control apparatuses 1 located in the respective zones of the temperature control object 60 may differently control the temperatures of the zones by setting different temperature conditions of the heat source parts 50, while uniformly controlling the temperature of one zone where each of the temperature control apparatuses 1 is located.

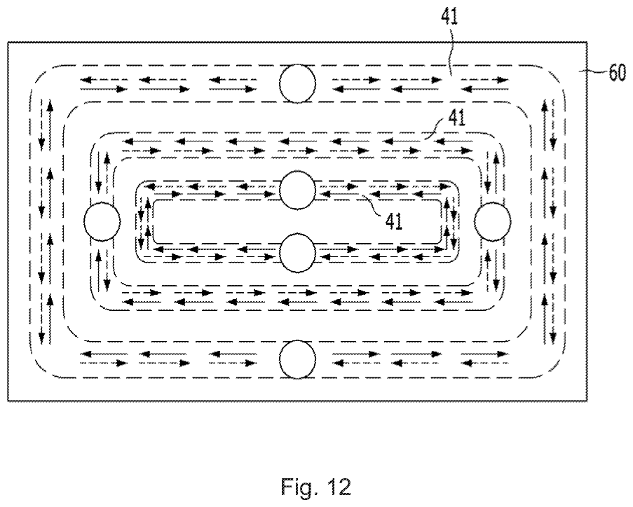

FIG. 12 is a plan view illustrating a flow path line 40 formed by a structure in which a plurality of temperature control apparatuses 1 are coupled to each other.

As illustrated in FIG. 12, a plurality of internal flow path lines 41 may be provided inside the temperature control object 60 along the inner perimeter of the temperature control object 60. The plurality of internal flow path lines 41 may be configured such that the perimeter lengths thereof may gradually decrease toward the center of the temperature control object 60.

An internal flow path line 41 having the largest perimeter length formed along the inner perimeter (in the drawing of FIG. 12) of the temperature control object 60 may be a first internal flow path line of the first temperature control apparatus. circular cross-section illustrated on the upper side in the drawing of FIG. 12 on the first internal flow path line may be a flow path line connected to a first operating part 10 of the first temperature control apparatus, and a circular cross-section illustrated on the lower side in the drawing on the first internal flow path line may be a flow path line connected to a second operating part 20 of the first temperature control apparatus. In FIG. 12, the dotted arrow illustrated on the first internal flow path line indicates the flow direction of the temperature control medium flowing by the operation of the first operating part 10 of the first temperature control apparatus, and the solid arrow indicates the flow direction of the temperature control medium flowing by the operation of the second operating part 20 of the first temperature control apparatus.

In FIG. 12, a second internal flow path line of the second temperature control apparatus is disposed inside the first internal flow path line. The second internal flow path line may be formed to have a smaller perimeter length than the first internal flow path line. A circular cross-section illustrated on the left side in the drawing of FIG. 12 on the second internal flow path line may be a flow path line connected to a first operating part 10 of the second temperature control apparatus, and a circular cross-section illustrated on the right side in the drawing on the second internal flow path line may be a flow path line connected to a second operating part 20 of the second temperature control apparatus.

In FIG. 12, the dotted arrow illustrated on the second internal flow path line indicates the flow direction of the temperature control medium flowing by the operation of the first operating part 10 of the second temperature control apparatus, and the solid arrow indicates the flow direction of the temperature control medium flowing by the operation of the second operating part 20 of the second temperature control apparatus.

In FIG. 12, a third internal flow path line of the third temperature control apparatus is disposed inside the second internal flow path line. The third internal flow path line may be formed to have a smaller perimeter length than the second internal flow path line. A circular cross-section illustrated on the upper side in the drawing of FIG. 12 on the third internal flow path line may be a flow path line connected to a first operating part of the third temperature control apparatus, and a circular cross-section illustrated on the lower side in the drawing on the third internal flow path line may be a flow path line connected to a second operating part 20 of the third temperature control apparatus.

In FIG. 12, the dotted arrow illustrated on the third internal flow path line indicates the flow direction of the temperature control medium flowing by the operation of the first operating part 10 of the third temperature control apparatus, and the solid arrow indicates the flow direction of the temperature control medium flowing by the operation of the second operating part 20 of the third temperature control apparatus.

Due to the above structure, the temperature of a central portion and a peripheral portion of the temperature control object 60 can be uniformly controlled, thereby making it possible to ensure uniformity of the internal temperature of the entire temperature control object 60. In addition, it is possible to control the temperature of the temperature control object 60 more quickly through the provision of a plurality of temperature control apparatuses 1, 1′, and 1″.

According to the present invention, since the first and second operating parts 10 and 20 are coupled to one flow line 40, it is possible to control the temperature control medium to flow bidirectionally in the flow path line 40 by the alternating operation of the first and second operating parts 10 and 20. In this case, in order to reduce the temperature deviation of the temperature control medium which may occur at the first end and the second end of the flow path line 40, the present invention may include the heat source part 50 on the flow path line 40 between each operating part and the temperature control object 60. The temperature control medium in which the temperature variation is reduced by the heat source part 50 can control the temperature inside the temperature control object 60 while flowing bidirectionally in the flow path line 40.

In the present invention, while maintaining the above structure as a basic principle, by arranging the flow path line 40 in various structures in addition to the structure of the flow path line 40 with reference to FIGS. 1 to 10, there is provided an effect of ensuring uniformity of the temperature inside the temperature control object 60.

As described above, the present invention has been described with reference to the exemplary embodiments. However, those skilled in the art will appreciate that various modifications, additions and substitutions are possible, without departing from the scope and spirit of the invention as disclosed in the accompanying claims.

What is claimed is:

1. A temperature control apparatus, comprising:
a flow path line being in communication with an inside of a temperature control object;
a first operating part coupled to a first end of the flow path line;
a second operating part coupled to a second end of the flow path line; and
a heat source part supplying heat energy to or depriving the heat energy of a temperature control medium of the flow path line,
wherein the temperature control medium controls a temperature of the temperature control object while flowing bidirectionally in the flow path line by operation of the first and second operating parts.

2. The temperature control apparatus of claim 1, wherein the first and second operating parts are piston pumps.

3. The temperature control apparatus of claim 2, wherein an air layer is provided between an end of each of the piston pumps and the temperature control medium.

4. The temperature control apparatus of claim 1, wherein the heat source part comprises a first heat source part provided on the flow path line between the first operating part and the temperature control object.

5. The temperature control apparatus of claim 1, wherein the heat source part comprises a second heat source part provided on the flow path line between the second operating part and the temperature control object.

6. The temperature control apparatus of claim 1, wherein the heat source part is provided on an outside of the flow path line.

7. The temperature control apparatus of claim 1, further comprising:
a buffer chamber provided on each of the flow path line between the first operating part and the temperature control object and the flow path line between the second operating part and the temperature control object, and controlling a temperature of the temperature control medium.

8. The temperature control apparatus of claim 6, wherein the heat source part is provided inside the buffer chamber.

9. The temperature control apparatus of claim 1, wherein the flow path line comprises:
an internal flow path line provided inside the temperature control object; and
an external flow path line provided outside the temperature control object,
wherein the internal flow path line includes a plurality of branch flow paths.

10. The temperature control apparatus of claim 9, wherein the plurality of branch flow paths are arranged in a planar manner.

11. The temperature control apparatus of claim 9, wherein the plurality of branch flow paths are arranged vertically.
